(19) United States
(12) Patent Application Publication
(10) Pub. No.: US 2002/0003245 A1
(43) Pub. Date: Jan. 10, 2002

(54) Compound semiconductor device and method of manufacturing the same

(75) Inventors: Takehiko Kato, Tokyo (JP); Kazuki Ota, Tokyo (JP); Hironobu Miyamoto, Tokyo (JP); Naotaka Iwata, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/777,910

(22) Filed: Feb. 7, 2001

(30) Foreign Application Priority Data
Feb. 28, 2000 (JP) 2000-051962

(51) Int. Cl. H01L 21/337; H01L 29/80; H01L 31/112; C30B 1/00; H01L 21/20; H01L 21/36

(52) U.S. Cl. 257/279; 438/186; 438/191; 257/256

(57) ABSTRACT

P-type impurities in a gate electrode is positively made to diffuse into a p-type impurity diffusion layer and an electrical p-n junction face in a gate electrode region is formed either within or on the bottom face of the p-type impurity diffusion layer, and thereby the effect that an interface state arising on a regrowth interface has over the p-n junction face can be well suppressed. This results in an improvement in high frequency characteristic of the JFET.

### BACKGROUND OF THE INVENTION

The present invention is concerned with a high electron mobility transistor (referred to as HEMT hereinafter) composed of a group III-V compound semiconductor and more particularly with a FET (Field Effect Transistor) having a p-n junction in a gate region thereof (referred to as JFET hereinafter).

When a heterojunction is formed with an n-type compound semiconductor (an electron supply layer) such as n-AlGaAs or n-InGaP, and an i-type compound semiconductor (a channel layer) such as GaAs or InGaAs, as shown in FIG. 2(a), the n-type compound semiconductor supplies electrons for the i-type compound semiconductor. Being supplied, the electrons accumulate on the heterojunction interface in the i-type compound semiconductor, as shown in FIG. 2(b), and form a two-dimensional electron gas which functions as a channel. When these electrons are made to run in a channel layer that does not contain dopants, since no scattering by dopants takes place therein, the electrons achieve a high mobility, which can be exploited for the fabrication of the HEMT. Further, in recent years, the development has been earnestly being carried forward over the JFET in which a p-n junction is formed in a gate region of a HEMT and, with a reverse bias applied to the p-n junction, the channel width immediately under the gate is regulated and thereby the drain current is controlled. In addition to characteristics of high-speed and low-noise that the HEMT possesses, the JFET has the advantage of capability of high-current operation, having a high forward turn-on voltage of the gate. Accordingly, the enhancement type JFET, in particular, has been being put into practical use in fields of high-speed communication and satellite broadcasting.

However, the JFET has the following problems originating in the p-n junction face in the gate region.

Firstly, there are instances where an interface state is created on a regrowth interface between an electron supply layer and a gate electrode of FIG. 2(a), resulting from voids on the crystal surface, impurities such as oxides that are buried during the regrowth of crystal, discontinuities of the crystal lattice or the like. Once an interface state is created, electrons leak out through this. Therefore, the closeness with which the element follows the external signal decreases and high frequency characteristic thereof deteriorates greatly.

As a technique to suppress the effect of the interface sate, it is, for example, disclosed in Japanese Patent Application Laid-open No. 235042/1993 that an i-GaAs layer with a thickness of 30 nm or more is formed between a gate electrode and an n-GaAs layer so as to obtain a JFET of which the RF (Radio Frequency) output is difficult to saturate, linearity of the gain is of excellent quality and the gate withstand voltage is sufficient. Although the method described in this publication can hinder the electric field centralization from developing immediately under the gate electrode, however, the interface state persists in the vicinity of the p-n junction face. Consequently, the obtained elements, in some cases, demonstrate insufficient high frequency characteristic. Moreover, because the film thickness of the n-GaAs layer is required to be 30 nm or more, controllability of the drain current with respect to the gate voltage may become low or even fabrication of the enhancement type JFET itself may become difficult.

In Japanese Patent Application Laid-open No. 64924/1998, it is disclosed that the selective epitaxial crystal growth method is employed for the fabrication of a gate electrode so that formation of gaps between a gate electrode and a semiconductor substrate may be prevented. The method described in this publication can certainly suppress creation of the interface state that, in the first instance, occurs due to the presence of gaps. It is, however, considered difficult to suppress the creation of the interface state caused by surface defects, impurities such as oxides, discontinuities of the crystal lattice or the like, with this method.

The second problem results from a fact that p-type impurities such as Zn, Be, Mg, C or Cd which are doped into a gate electrode diffuse into an electron supply layer at high speed. Since the steepness of the gradient of energy level at the p-n junction face in this case becomes reduced, controllability of the threshold voltage decreases, which may lead to a decrease in yield. There are also instances where the gate capacitance increases and high frequency characteristic of the obtained element deteriorates considerably.

As an example of a technique to suppress the diffusion of the p-type impurities doped into the gate electrode, it is disclosed in Japanese Patent Application Laid-open No.83808/1996 that an undoped semiconductor layer is laid between the opposite end faces of a source and a drain, and, without allowing p-type impurities to diffuse out, a p-n junction gate that includes this undoped semiconductor layer is fabricated. While this method can improve controllability of the threshold voltage and reduce the gate parasitic capacitance, it is considered difficult that this method succeeds in suppressing the diffusion of the p-type impurities, once formation of the p-n junction gate is completed.

Further, in Japanese Patent Application Laid-open No.214403/1999, it is disclosed that, in forming a gate electrode, either p-type impurities are implanted into a semiconductor layer containing B or implantation of B is carried out concurrently with implantation of p-type impurities, whereby the diffusion of the p-type impurities is controlled. In the method described in this publication, however, it is necessary to use a given amount of B to control the diffusion of the p-type impurities so that there is a possibility to damage characteristics of the compound semiconductor substrate.

In either conventional method described in these publications, the diffusion of p-type impurities across the p-n junction face is treated negatively and its suppression and control are the prime object aimed at.

The third problem relates to a faulty contact of a regrowth interface that is formed between an electron supply layer and a gate electrode when the gate electrode is grown on the electron supply layer. In effect, there are instances where the contact of the regrowth interface becomes defective due to a difference between lattice contacts of a compound semiconductor constituting the gate electrode and another compound semiconductor constituting the electron supply layer or due to the presence of metal oxides on the surface of the electron supply layer. If many faulty contact points are produced on a regrowth interface, the lifetime of the obtained element becomes shortened and the yield thereof, lowered.

### SUMMARY OF THE INVENTION

Accordingly, an object of the present invention is to provide, by positively making use of diffusion of p-type impurities across a p-n junction face, a JFET in which the effect of the interface state is well suppressed and the steepness of the gradient of energy level at the p-n junction face is improved, and besides an excellent contact of a regrowth interface is realized, and a manufacturing method thereof.

In light of the above problems, the present invention provides a compound semiconductor device, comprising:

a channel layer composed of an i-type compound semiconductor,

an electron supply layer composed of an n-type compound semiconductor, being formed on said channel layer,

a p-type impurity diffusion layer composed of either an i-type compound semiconductor or a p-type compound semiconductor, being formed on said electron supply layer, and

a gate electrode composed of a p-type compound semiconductor, being formed on said p-type impurity diffusion layer; wherein:

an electrical p-n junction face between said electron supply layer and said gate electrode is formed either within said p-type impurity diffusion layer or on the bottom face of said p-type impurity diffusion layer.

Further, the present invention provides a method of manufacturing a compound semiconductor device, comprising the steps of:

forming a channel layer composed of an i-type compound semiconductor,

forming, on said channel layer, an electron supply layer composed of an n-type compound semiconductor,

forming, on said electron supply layer, a p-type impurity diffusion layer composed of either an i-type compound semiconductor or a p-type compound semiconductor,

forming, on said p-type impurity diffusion layer, a gate electrode composed of a p-type compound semiconductor, and

making p-type impurities diffuse into said p-type impurity diffusion layer and forming newly, beneath said gate electrode, a p-type compound semiconductor region capable to function as an additional gate electrode so that an electrical p-n junction face between said electron supply layer and said gate electrode may be formed either within said p-type impurity diffusion layer or on the bottom face of said p-type impurity diffusion layer.

In a JFET of the present invention, p-type impurities in a gate electrode is positively made to diffuse into a p-type impurity diffusion layer which is formed under the gate electrode and an electrical p-n junction face in a gate electrode region is formed either within or on the bottom face of the p-type impurity diffusion layer, whereby the effect that an interface state arising on a regrowth interface between the gate electrode and the p-type impurity diffusion layer has over the electrical p-n junction face in the gate electrode region can be well suppressed and excellent high frequency characteristic can be attained.

### BRIEF DESCRIPTION OF THE DRAWINGS

FIG. 1 is a pair of views in explaining the structure of a JFET according to the present invention.

FIG. 2 is a pair of views in explaining the structure of a conventional JFET.

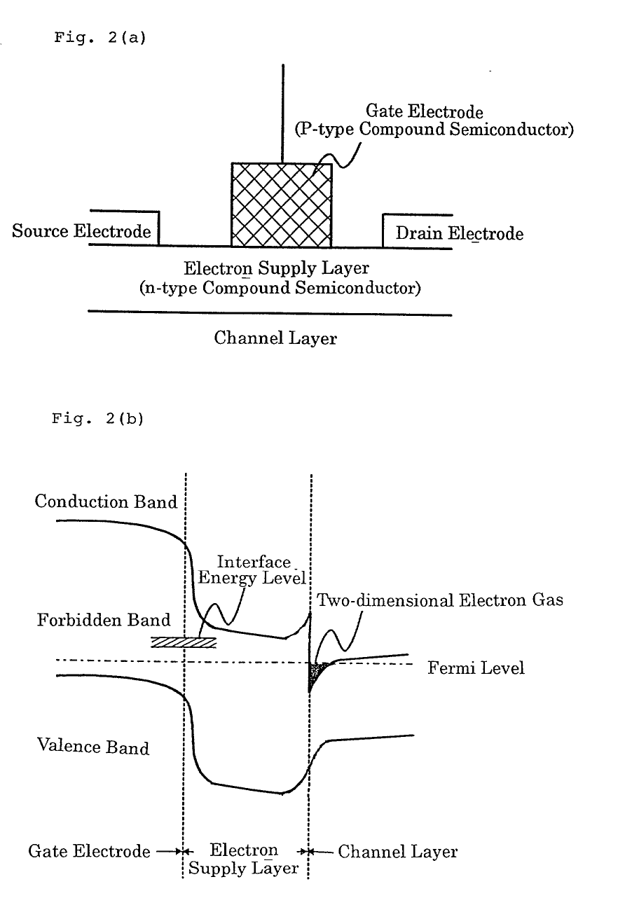

FIG. 3 is a series of cross-sectional views illustrating an embodiment of a JFET according to the present invention as well as the steps of a manufacturing method thereof.

FIG. 4 is a cross-sectional view illustrating another embodiment of a JFET according to the present invention.

FIG. 5 is a series of cross-sectional views illustrating another embodiment of a JFET according to the present invention as well as the steps of a manufacturing method thereof.

### DETAILED DESCRIPTION OF THE PREFERRED EMBODIMENTS

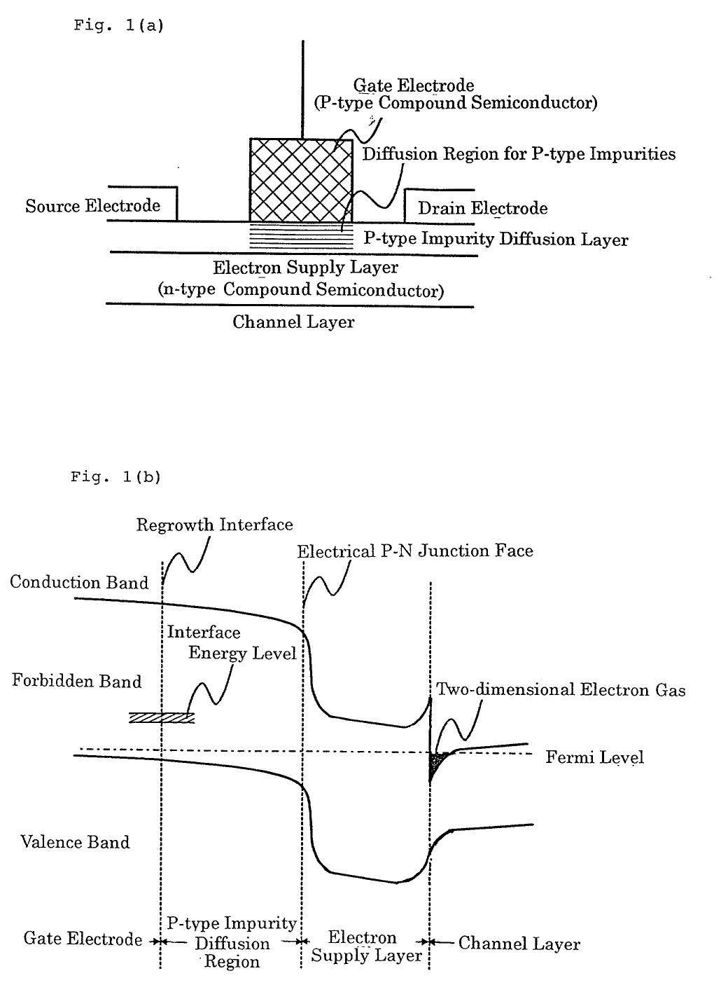

In a JFET according to the present invention, as shown in FIG. 1(a), a p-type impurity diffusion layer is set between a gate electrode and an electron supply layer and p-type impurities in the gate electrode is positively made to diffuse into the p-type impurity diffusion layer. As a result, a region in the p-type impurity diffusion layer into which p-type impurities have diffused has become composed of a p-type compound semiconductor, and this newly formed p-type compound semiconductor region functions electrically as an additional gate electrode. Consequently, the electrical p-n junction face in the gate region becomes situated on the end plane of the diffusion region for the p-type impurities and lying within the p-type impurity diffusion layer. Therefore, the electrical p-n junction face and a regrowth interface formed between the p-type impurity diffusion layer and the gate electrode become separated as much as the distance covered by the diffusion of the p-type impurities. Since the interface state arises on the regrowth interface, as shown in FIG. 1(b), the leakage of electrons on the electrical p-n junction face which occurs through the interface state is suppressed and the closeness with which the element follows the external signal is increased and high frequency characteristic thereof is greatly improved.

In the present invention, these diffused impurities may be, in some cases, able to pass through the p-type impurity diffusion layer and reach the electron supply layer. However, because the electron supply layer is composed of an n-type compound semiconductor, p-type impurities that reach the inside of the electron supply layer are prevented from forming newly a p-type compound semiconductor region therein. Accordingly, the electrical p-n junction face in the gate region is, in this case, defined to be on the interface between the p-type impurity diffusion layer and the electron supply layer, that is, the bottom face of the p-type impurity diffusion layer so that excellent steepness thereat is provided. As a result, the gate capacitance of the obtained element becomes sufficiently low and high frequency characteristic, excellent.

The electrical p-n junction in the present invention is formed on the end face of the diffusion region by using the means that p-type impurities being contained in the p-type compound semiconductor layer such as the gate electrode which is formed in contact with and on the p-type impurity diffusion layer are made to diffuse into the p-type impurity diffusion layer. For such p-type impurities, those having a high diffusion velocity are favourable and, for example, Zn, Be, C or Cd can be employed. Further, if circumstances require, a mixture of two or more kinds of these p-type impurities can be utilized.

From the viewpoints of characteristics of the obtained gate electrode and diffusion efficiency of the p-type impurities, the dopant concentration for the above p-type impurities is set preferably not less than 1×10¹⁸ atm/cm³ and more preferably 5×10¹⁸ atm/cm³ and still more preferably not less than 1×10¹⁹ atm/cm³, but preferably not more than 1×10²² atm/cm³ and more preferably not more than 5×10²¹ atm/cm³ and still more preferably not more than 1×10²¹ atm/cm³.

In the above range of dopant concentration, p-type impurities are doped into GaAs, Al_{ξ}Gal₁-_{ξ}As ( 0<ξ<0.5 ) In_{η}Ga₁-_{η}P ( 0<η<0.5 ), In_{ζ}Ga₁-_{ζ}As ( 0<ζ<0.5 ) or the like. More specifically, from the viewpoints of balance between characteristics of the obtained compound semiconductor device, Zn-doped GaAs, Be-doped GaAs, C-doped GaAs or such can be cited as examples.

Further, with the object of securing a sufficient amount of p-type impurities for diffusion, using the MBE (Molecular Beam Epitaxy) method, the MOCVD (Metal Organic Chemical Vapour Deposition) method, the LPE (Liquid Phase Epitaxy ) method or the like, a gate electrode is grown to a thickness that is preferably not less than 10 nm and more preferably not less than 20 nm, but preferably not more than 200 nm and more preferably not more than 100 nm.

With respect to the gate electrode described above, it is favourably formed through doping p-type impurities into a compound semiconductor having the same composition as the p-type impurity diffusion layer. Because the gate electrode is, in this case, formed to be in the state lattice-matched to the p-type impurity diffusion layer, the contact of a regrowth interface formed between the gate electrode and the p-type impurity diffusion layer is in excellent condition. This results in a longer lifetime and a higher yield for the obtained element.

Further, the gate electrode and the p-type impurity diffusion layer are favourably composed of a compound semiconductor containing no Al. Al is easily oxidized to become aluminium oxide. If the gate electrode and the p-type impurity diffusion layer do not contain Al, the occurrence that the regrowth interface formed between the gate electrode and the p-type impurity diffusion layer is disturbed by the presence of metal oxides is kept in check so that the contact of the regrowth interface obtained is in good condition. This results in a longer lifetime and a higher yield for the obtained element.

However, when the gate electrode is heavily doped and in a degenerated state, there are instances where the effect of oxidation described above does not become significant in high frequency region. In these instances, it does not matter if the gate electrode contains Al or not.

With regard to a compound semiconductor constituting the p-type impurity diffusion layer in the present invention, it is favourable to use one that allows p-type impurities to diffuse rapidly so that a new p-type compound semiconductor region capable to function as an additional gate electrode could be formed well. For example, as an i-type compound semiconductor, undoped GaAs and undoped In_{η}Ga_{1-η}P ( 0<η<0.5 ) can be cited. As a p-type compound semiconductor, ones that p-type impurities such as C or Be are doped into these i-type compound semiconductors can be given as examples. More specifically, undoped GaAs, C-doped GaAs or the like is favourable from the viewpoints of balance between characteristics of the obtained compound semiconductor device.

In the case that the p-type impurity diffusion layer is composed of such a p-type compound semiconductor as described above, even if the amount of diffused p-type impurities, as a whole, is lacking, a p-type compound semiconductor region having a sufficient dopant concentration therein can be formed in the p-type impurity diffusion layer. However, if the p-type impurity diffusion layer is composed of a p-type compound semiconductor with a high dopant concentration, channel electrons in regions other than the region immediately under the gate electrode may become exhausted and ON-state resistance may become large.

For the above reasons, in the case that the p-type impurity diffusion layer is composed of a p-type compound semiconductor, the concentration of p-type impurities is preferably not less than 1×10¹⁷ atm/cm³ and more preferably not less than 1×10¹⁸ atm/cm³, but preferably not more than 1×10²¹ atm/cm³ and more preferably not more than 1×10²⁰ atm/cm³.

Further, to attain balance between the characteristics of the obtained element, the thickness of the p-type impurity diffusion layer is set preferably not less than 2 nm and more preferably not less than 5 nm, but preferably not more than 50 nm and more preferably not more than 30 nm.

Such a p-type impurity diffusion layer as described above can be grown by the MBE method, the MOCVD method or the like. Since the regrowth temperature for the p-type impurity diffusion layer affects the crystal nature of the obtained p-type impurity diffusion layer, the temperature during formation of the p-type impurity diffusion layer may have influence on the length of diffusion that the p-type impurities subsequently carry out. Accordingly, the p-type impurity diffusion layer is, in some cases, grown at a temperature above 400° C.

In the case that the p-type impurity diffusion layer does not contain Al, oxidation of lower layers such as the electron supply layer can be suppressed by setting the thickness of the p-type impurity diffusion layer in such a range as described above.

As occasion demands, the p-type impurity diffusion layer can have a layered structure made of two or more layers of either an i-type compound semiconductor or a p-type compound semiconductor. Such a p-type impurity diffusion layer with a layered structure is favourable when an element is manufactured through a step wherein the diffusion length of the p-type impurities becomes long, owing to a treatment performed at a high temperature.

A manufacturing method of a JFET according to the present invention comprises the step of making p-type impurities diffuse into the p-type impurity diffuse layer and forming newly, beneath the gate electrode, a p-type compound semiconductor region capable to function as an additional gate electrode.

This step of making p-type impurities diffuse into the p-type impurity diffuse layer and forming newly a p-type compound semiconductor region may be performed simultaneously with forming a gate electrode that is composed of a p-type compound semiconductor, or alternatively carried out through annealing or the like after the gate electrode is formed. On the one hand, when the p-type compound semiconductor region is formed simultaneously with fabrication of the gate electrode, the steps of a manufacturing method of a compound semiconductor device become favourably simplified. On the other hand, when formation of the p-type compound semiconductor region is carried out after the gate electrode is first fabricated, the degree of freedom for the forming conditions increases favourably.

In order to form an excellent p-type compound semiconductor region without harming the previously-formed compound semiconductor layers, the step of forming newly a p-type compound semiconductor region is conducted favourably at or above 400° C. and more favourably at or above 430° C. and still more favourably at or above 450° C., but favourably at or below 700° C. and more favourably at or below 680° C. and still more favourably at or below 650° C.

Furthermore, for the same reason as mentioned above, the step of forming newly a p-type compound semiconductor region lasts favourably 30 seconds or longer and more favourably 45 seconds or longer and still more favourably 1 minute or longer, but favourably 20 minutes or shorter and more favourably 15 minutes or shorter and still more favourably 10 minutes or shorter.

Among all the steps of a method of manufacturing a compound semiconductor device of the present invention, the step of forming newly a p-type compound semiconductor region is favourably performed at the highest temperature so as to cause no damage to other compound semiconductor layers and prevent the p-type impurities from diffusing.

Further, when a gate electrode is grown on a p-type impurity diffusion layer, if the p-type impurity diffusion layer does not contain Al, formation of metal oxides on the regrowth interface between the p-type impurity diffusion layer and the gate electrode is suppressed. Moreover, if the gate electrode does not contain Al, either, oxidation of the gate electrode is kept in check during diffusion of the p-type impurities.

As described above, in the present invention, with manufacturing conditions such as temperature and time period being strictly controlled, an excellent p-type compound semiconductor region is newly formed. This enables the fabrication of a JFET wherein, unlike the conventional ones, the effect of the interface state is well suppressed and the steepness of the gradient of energy level at the p-n junction face is improved and besides an excellent contact of a regrowth interface is realized.

In the present invention, it is also possible to form a p-type impurity inactive layer composed of either an i-type compound semiconductor or an n-type compound semiconductor between the electron supply layer and the p-type impurity diffusion layer. In this case, even if p-type impurities pass through the p-type impurity diffusion layer and reach the p-type impurity inactive layer, new formation of a p-type compound semiconductor region in the p-type impurity inactive layer is hindered.

Accordingly, in this case, the electrical p-n junction face in the gate region is defined to be on the interface between the p-type impurity diffusion layer and the p-type impurity inactive layer, that is, the bottom face of the p-type impurity diffusion layer so that excellent steepness thereat is provided. As a result, variations of characteristics of the obtained element are kept in check, and besides the gate capacitance thereof can be made sufficiently low so that high frequency characteristic becomes excellent.

With regard to a compound semiconductor constituting such a p-type impurity inactive layer, it is favourable to use one that makes p-type impurities diffuse slowly and, thus, makes formation of a new p-type compound semiconductor region that is capable to function as an additional gate electrode difficult. For example, as an i-type compound semiconductor, undoped Al_{y}Ga_{1-y}As ( 0<Y<0.5 ) and undoped In_{z}Ga_{1-z}P ( 0<Z<0.5 ) can be cited. As a p-type compound semiconductor, ones that n-type impurities such as Si are doped into these i-type compound semiconductors can be given as examples.

In the case that the p-type impurity inactive layer is composed of an n-type compound semiconductor, for the purpose of hindering sufficiently new formation of a p-type compound semiconductor region without worsening characteristics of the element as a whole, the dopant concentration of the n-type impurities is set preferably not less than 1×10¹⁶ atm/cm³ and more preferably not less than 1×10¹⁷ atm/cm³, but preferably not more than 1×10²⁰ atm/cm³ and more preferably not more than 1×10¹⁹ atm/cm³.

Further, in order to attain balance between characteristics of the obtained element and prevent the p-type impurities that diffuse out of the gate electrode from passing through, the thickness of the p-type impurity inactive layer is set preferably not less than 2 nm and more preferably not less than 5 nm, but preferably not more than 100 nm and more preferably not more than 30 nm. Such a p-type impurity inactive layer as described above can be grown by the MBE method, the MOCVD method or the like at a temperature above 400° C., after forming an electron supply layer but before forming a p-type impurity diffusion layer.

An electron supply layer in the present invention can be composed of a known compound semiconductor. For example, n-type compound semiconductors wherein Si, Se, S, Sn or the like is doped into Al_{X}Ga_{1-X}As ( 0<X<0.5 ), In_{Z}Ga_{1-Z}P ( 0<Z<0.5 ) and the like can be cited. More specifically, Si-doped Al_{X}Ga_{1-X}As ( 0<X<0.5 ) or the like is used.

Further, for the purpose of hindering new formation of a p-type compound semiconductor region sufficiently without worsening characteristics of the element as a whole, the dopant concentration of the n-type impurities in the electron supply layer is set preferably not less than 1×10¹⁷ atm/cm³ and more preferably not less than 1×10¹⁸ atm/cm³ but preferably not more than 1×10²⁰ atm/cm³ and more preferably not more than 1×10¹⁹ atm/cm³.

Further, the thickness of the electron supply layer is preferably set not less than 3 nm but not more than 30 nm, and the MBE method, the MOCVD method or the like can be employed to grow the layer.

A channel layer in the present invention can be composed of a known compound semiconductor such as undoped In_{ζ}Ga_{1-ζ}As ( 0<ζ<0.5 ). Further, the thickness of the channel layer is preferably set not less than 5 nm but not more than 50 nm, and the MBE method, the MOCVD method or the like can be employed to grow the layer.

Further, in the present invention, in addition to the layers described above, a buffer layer, a spacer layer or such can be formed, as required.

Further, an etching stopper layer may be also formed therein. There are, in particular, instances where an etching stopper layer containing p-type impurities is formed over the p-type impurity diffusion layer and, by making the p-type impurities in the etching stopper layer diffuse into the p-type impurity diffusion layer, a p-type compound semiconductor region is newly formed. In such a structure, diffusion of the p-type impurities may be made concurrently with formation of the etching stopper layer. Alternatively, diffusion of the p-type impurities may be carried out while forming the gate electrode after the etching stopper layer is formed or even separately at the time of annealing.

Through formation of such a buffer layer, a spacer layer or an etching stopper layer as described above, the obtained element can achieve still better balance between characteristics thereof.

In a JFET according to the present invention, the effect of the interface state on the p-n junction face is well suppressed and the steepness of the gradient of energy level at the p-n junction face is improved and besides an excellent contact of a regrowth interface is realized. This improves high frequency characteristic and enhances controllability of the threshold voltage. In some cases, an increase in the maximum output during high-output operation amounts to more than 10%.

Next, preferred embodiments of the present invention are described in detail below.

Embodiment 1

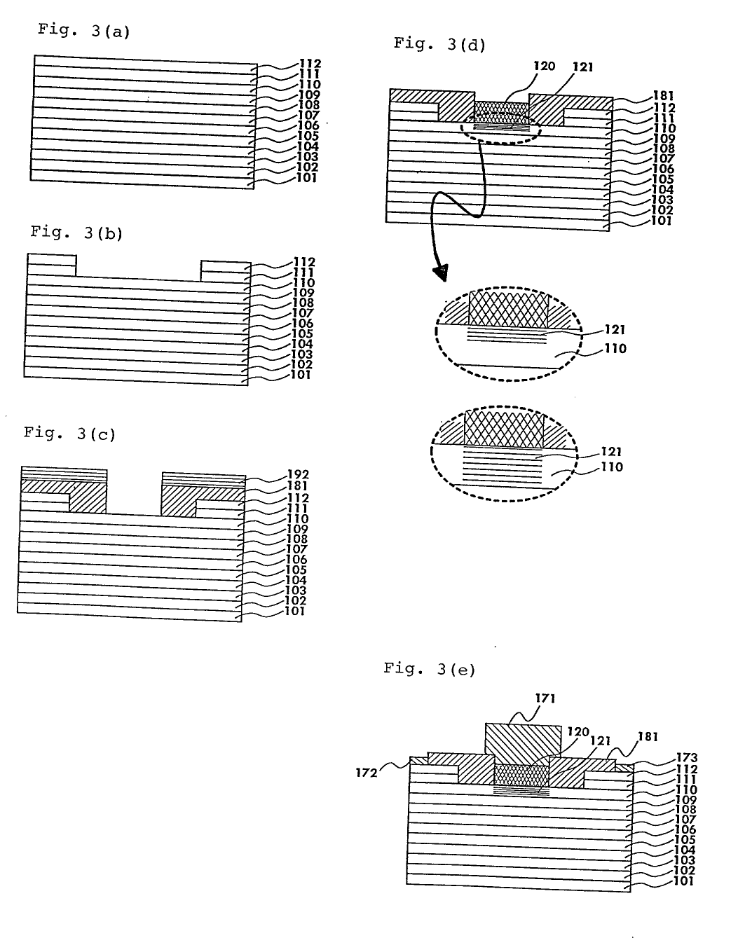

Referring to FIG. 3, Embodiment 1 is described. First, on a semi-insulating substrate 101, a GaAs buffer layer 102 with a thickness of 400 nm, an Al_{0.2}Ga_{0.8}As buffer layer 103 with a thickness of 100 nm, a 4×10¹⁸ atm/cm³ Si-doped Al_{0.2}Ga_{0.8}As electron supply layer 104 with a thickness of 4 nm, an undoped Al_{0.2}Ga_{0.8}As spacer layer 105 with a thickness of 2 nm, an undoped In_{0.2}Ga_{0.8}As channel layer 106 with a thickness of 15 nm, an undoped Al_{0.2}Ga_{0.8}As spacer layer 107 with a thickness of 2 nm, a 4×10¹⁸ atm/cm³ Si-doped Al_{0.2}Ga_{0.8}As electron supply layer 108 with a thickness of 12 nm, a p-type impurity inactive layer 109 composed of undoped Al_{0.2}Ga_{0.8}As with a thickness of 15 nm, a p-type impurity diffusion layer 110 composed of undoped GaAs with a thickness of 5 nm, an Al_{0.2}Ga_{0.8}As etching stopper layer 111 with a thickness of 5 nm and a GaAs ohmic contact layer 112 with a thickness of 100 nm are formed, in succession, by epitaxial growth, using either the MBE method or the MOCVD method so that a layered structure shown in FIG. 3(a) may be fabricated.

Next, on that fabricated structure, a mask is formed, and, using the layer 111 as an etching stopper layer, an opening is made in the ohmic contact layer 112 by dry etching. The mask and a portion of the etching stopper layer 111 in the opening section are, then, removed. The structure obtained is shown in FIG. 3(b).

A SiO₂ film 181 and a mask 192 having an opening for the gate recess section are successively grown thereon and then, by etching the SiO₂ film 181, the p-type impurity diffusion layer 110 is exposed in the gate opening section. FIG. 3(c) shows the structure after etching the SiO₂ film 181.

Further, after the mask 192 is removed, a 1×10²⁰ atm/cm³ Zn-doped GaAs gate electrode 120 is selectively grown, using the SiO₂ film 181 as a mask, on the p-type impurity diffusion layer 110 for 2 minutes at a growth temperature of 500° C. in a MOCVD apparatus. During this selective growth, as shown in FIG. 3(d), Zn that is the p-type impurities in the gate electrode 120 is made to diffuse into the p-type impurity diffusion layer 110 and a new p-type compound semiconductor region 121 is formed to function as an additional gate electrode. Since the p-type impurity diffusion layer 110 does not contain Al, production of metal oxides on the regrowth interface formed between these two layers is kept in check. Moreover, lattice constants of the p-type impurity diffusion layer 110 and the gate electrode 120 coincide. By these reasons, the contact of the regrowth interface hereat is in excellent condition.

As shown in enlarged views each surrounded by an ellipse in FIG. 3(d), diffusion of Zn is, in some cases, confined within the p-type impurity diffusion layer 110 and, in other cases, allowed to reach the p-type impurity inactive layer 109. Especially when diffusion of Zn reaches the p-type impurity inactive layer 109, because new formation of a p-type compound semiconductor region within the p-type impurity inactive layer is hindered, the electrical p-n junction face in the gate region is defined to be on the interface between the p-type impurity diffusion layer 110 and the p-type impurity inactive layer 109, that is, the bottom face of the p-type impurity diffusion layer 110. This provides the steepness at the p-n junction face in the gate region. As a result, controllability of threshold voltage is improved and a JFET having a sufficiently reduced gate capacitance can be obtained.

Subsequently, on the gate electrode 120, a gate electrode interconnection 171 is formed and then a source electrode 172 and a drain electrode 173 are formed, accomplishing the structure of FIG. 3(e). In the case of such a structure, the interface state arises on the regrowth interface between the p-type impurity diffusion layer 110 and the gate electrode 120. Nevertheless, the electrical p-n junction face in the gate region is present either within the p-type impurity diffusion layer 110 or on the bottom face of the p-type impurity diffusion layer 110. Therefore, the effect of the interface state of the regrowth interface in JFET operation is well suppressed and excellent high frequency characteristics can be attained.

Embodiment 2

A JFET can be manufactured in the same way as Embodiment 1 except that the p-type impurity diffusion layer 110 is a 1×10¹⁹ atm/cm³ C-doped GaAs layer with a thickness of 5 nm.

In this case, too, a new p-type compound semiconductor region 121 having a sufficient concentration of p-type impurities is formed within the p-type impurity diffusion layer 110. Further, in regions other than the region beneath the gate electrode 120, electrons in the channel layer 106 can never be exhausted.

Embodiment 3

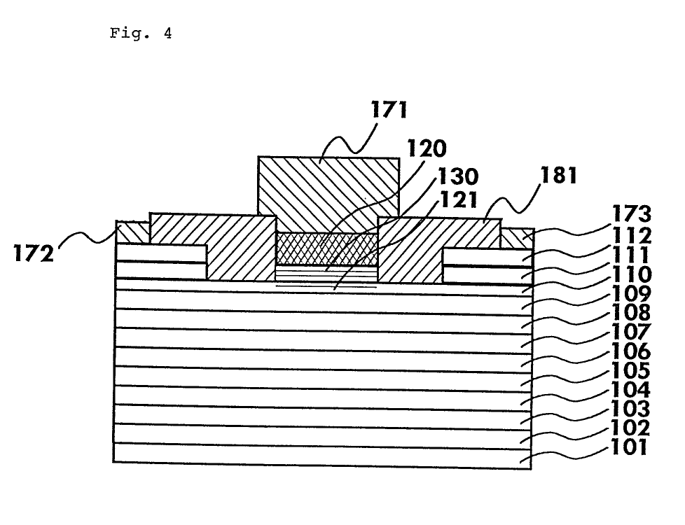

As shown in FIG. 4, a JFET can be manufactured in the same way as Embodiment 1 except that the thickness of the p-type impurity diffusion layer 110 is set to be 3 nm and a second p-type impurity diffusion layer 130 composed of GaAs with a thickness of 2 nm is formed, prior to the formation of the gate electrode 120.

A p-type compound semiconductor region 121 is formed, in this case, as well. The above structure is, however, particularly effective in the case that an element is manufactured through a step wherein the diffusion length of p-type impurities becomes long, owing to a treatment performed at a high temperature.

Embodiment 4

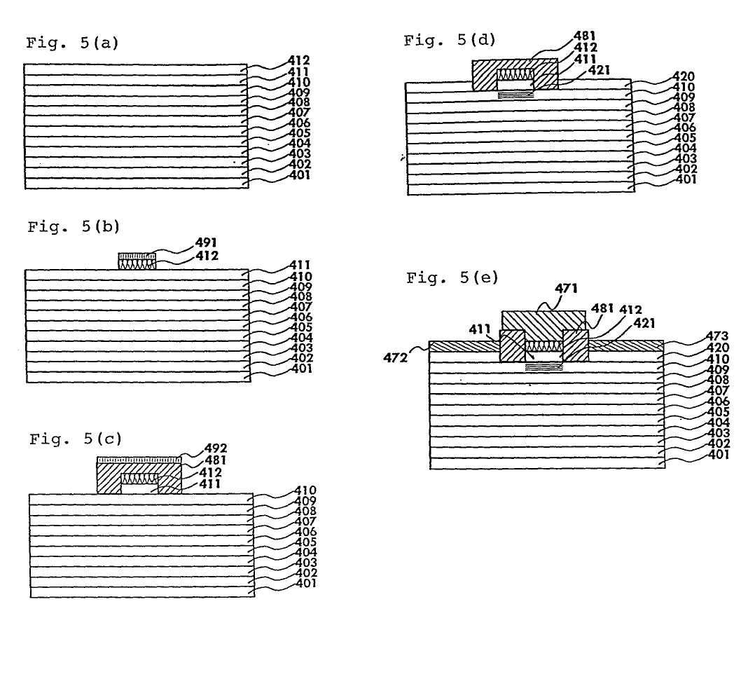

Referring to FIG. 5, Embodiment 4 is described. First, on a semi-insulating substrate 401, a GaAs buffer layer 402 with a thickness of 400 nm, an Al_{0.2}Ga_{0.8}As buffer layer 403 with a thickness of 100 nm, a 4×10¹⁸ atm/cm³ Si-doped Al_{0.2}Ga_{0.8}As electron supply layer 404 with a thickness of 4 nm, an undoped Al_{0.2}Ga_{0.8}As spacer layer 405 with a thickness of 2 nm, an undoped In_{0.2}Ga_{0.8}As channel layer 406 with a thickness of 15 nm, an undoped Al_{0.2}Ga_{0.8}As spacer layer 407 with a thickness of 2 nm, a 4×10¹⁸ atm/cm³ Si-doped Al_{0.2}Ga_{0.8}As electron supply layer 408 with a thickness of 12 nm, a p-type impurity inactive layer 409 composed of undoped Al_{0.2}Ga_{0.8}As with a thickness of 15 nm, a p-type impurity diffusion layer 410 composed of undoped GaAs with a thickness of 15 nm, a 1.0×10²⁰ atm/cm³ Zn-doped Al_{0.2}Ga_{0.8}As etching stopper layer 411 with a thickness of 5 nm and a 1.0×10²⁰ atm/cm³ Zn-doped GaAs gate electrode layer 412 with a thickness of 50 nm are formed, in succession, by epitaxial growth, using either the MBE method or the MOCVD method. FIG. 5(a) shows the layered structure after the epitaxial growth. Further, two or more layers selected from the group consisting of layers composed of AlGaAs 404, 405, 407, 408, 409 and 411 can be composed of InGaP instead. It is also possible to dope the layer of AlGaAs 409, for example, with 4×10¹⁸ atm/cm³ Si.

Next, on that obtained layered structure, a mask 491 is formed and the gate electrode layer 412 overlying the etching stopper layer 411 is etched. The structure obtained is shown in FIG. 5(b).

Subsequently, the mask 491 and a portion of the etching stopper layer 411 other than the gate electrode section are removed. A SiO₂ film 481 and a mask 492 having an opening for the ohmic contact section are successively grown thereon and then, by etching the SiO₂ film 481, the p-type impurity diffusion layer 410 is exposed in the ohmic contact section. FIG. 5(c) shows the structure after etching the SiO₂ film 481.

Further, after the mask 492 is removed, a 4×10¹⁸ atm/cm³ Si-doped GaAs ohmic contact layer 420 is selectively grown, using the SiO₂ film 481 as a mask, on the p-type impurity diffusion layer 410 for 10 minutes at a growth temperature of 500° C. During this selective growth, as shown in FIG. 5(d), Zn in the etching stopper layer 411 and/or the gate electrode layer 412 is made to diffuse into the p-type impurity diffusion layer 410. FIG. 5(d) shows the structure after the selective growth. Zn diffuses into the portion 421 of FIG. 5(d). In this case, too, like Embodiment 1, an electrical p-n junction face in the gate region is formed either within or on the bottom face of the p-type impurity diffusion layer 410.

Subsequently, an opening is made so as to connect the SiO₂ film 481 with the gate electrode layer 412, and then a gate electrode 471, a source electrode 472 and a drain electrode 473 are each formed to accomplish a JFET shown in FIG. 5(e).

In a JFET manufactured in this manner, the effect of the interface state on the p-n junction face is well suppressed and the steepness of the gradient of energy level at the p-n junction face is improved and besides an excellent contact of the regrowth interface is realized.

Embodiment 5

A JFET can be manufactured in the same way as Embodiment 4 except that the p-type impurity diffusion layer 410 is a 1×10¹⁹ atm/cm³ C-doped GaAs layer with a thickness of 5 nm.

In this case, too, a new p-type compound semiconductor region 421 having a sufficient concentration of p-type impurities is formed within the p-type impurity diffusion layer 410. Further, the depletion of electrons never occurs in the p-type impurity inactive layer 409, the electron supply layer 408 and such.

What is claimed is:

1. A compound semiconductor device, comprising:
a channel layer composed of an i-type compound semiconductor,
an electron supply layer composed of an n-type compound semiconductor, being formed on said channel layer,
a p-type impurity diffusion layer composed of either an i-type compound semiconductor or a p-type compound semiconductor, being formed on said electron supply layer, and
a gate electrode composed of a p-type compound semiconductor, being formed on said p-type impurity diffusion layer; wherein:
an electrical p-n junction face between said electron supply layer and said gate electrode is formed either within said p-type impurity diffusion layer or on the bottom face of said p-type impurity diffusion layer.

2. A compound semiconductor device according to claim 1, wherein said p-n junction face is formed by diffusing one or more kinds of p-type impurities that are selected from the group consisting of Zn, Be, Mg, C and Cd into said p-type impurity diffusion layer.

3. A compound semiconductor device according to claim 1, wherein said gate electrode is formed by doping p-type impurities into a compound semiconductor having the same composition as said p-type impurity diffusion layer.

4. A compound semiconductor device according to claim 1, wherein said p-type impurity diffusion layer is composed of a compound semiconductor containing no Al.

5. A compound semiconductor device according to claim 1, wherein said p-type impurity diffusion layer is composed of either undoped GaAs or C-doped GaAs.

6. A compound semiconductor device according to claim 1, wherein said electron supply layer is composed of Si-doped Al_{X}Ga_{1-X}As ( 0<X<0.5 ).

7. A compound semiconductor device according to claim 1, wherein said gate electrode is composed of Zn-doped GaAs, Be-doped GaAs or C-doped GaAs.

8. A compound semiconductor device according to claim 1, wherein a p-type impurity inactive layer composed of either an i-type compound semiconductor or an n-type compound semiconductor is formed between said electron supply layer and said p-type impurity diffusion layer.

9. A compound semiconductor device according to claim 8, wherein said p-type impurity inactive layer is composed of either undoped Al_{Y}Ga_{1-Y}As ( 0<Y<0.5 ) or undoped In_{Z}Ga_{1-Z}P ( 0<Z<0.5 ).

10. A method of manufacturing a compound semiconductor device, comprising the steps of:
forming a channel layer composed of an i-type compound semiconductor,
forming, on said channel layer, an electron supply layer composed of an n-type compound semiconductor,
forming, on said electron supply layer, a p-type impurity diffusion layer composed of either an i-type compound semiconductor or a p-type compound semiconductor,
forming, on said p-type impurity diffusion layer, a gate electrode composed of a p-type compound semiconductor, and
making p-type impurities diffuse into said p-type impurity diffusion layer and forming newly, beneath said gate electrode, a p-type compound semiconductor region capable to function as an additional gate electrode so that an electrical p-n junction face between said electron supply layer and said gate electrode may be formed either within said p-type impurity diffusion layer or on the bottom face of said p-type impurity diffusion layer.

11. A method of manufacturing a compound semiconductor device according to claim 10, wherein a p-type impurity inactive layer composed of either an i-type compound semiconductor or an n-type compound semiconductor is formed after forming said electron supply layer but before forming said p-type impurity diffusion layer.
